(19) United States
(12) Patent Application Publication
(10) Pub. No.: US 2007/0128751 A1
(43) Pub. Date: Jun. 7, 2007

(54) Display device having uniform brightness

(75) Inventors: Kye-hoon Lee, Suwon-si (KR); Won-yong Lee, Suwon-si (KR); Byung-jo Kang, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/583,732

(22) Filed: Oct. 20, 2006

(30) Foreign Application Priority Data
Dec. 2, 2005 (KR) 2005-0117056

(51) Int. Cl. H01L 21/00; H01L 33/00

(52) U.S. Cl. 438/34; 257/88

(57) ABSTRACT

A display device having a uniform brightness and control method thereof are provided, which includes a circuit board having a light emitting diode mounting area, a light source unit comprising a plurality of light emitting diodes mounted to the light emitting diode mounting area so that light emitting characteristics can be symmetrical around the center of the light emitting diode mounting area, a light uniformizing unit for creating a uniform light from the light emitting diodes, a micro display unit located in front of the light uniformizing unit, a projection lens unit located in front of the micro display unit, and a screen located in front of the projection lens unit. Thus, the display device provides uniform brightness and color.

### CROSS-REFERENCE TO RELATED APPLICATIONS

This application claims the benefit under 35 U.S.C. § 119(a) of Korean Patent Application No. 2005-0117056, filed on Dec. 2, 2005, in the Korean Intellectual Property Office, the entire disclosure of which is hereby incorporated by reference.

### BACKGROUND OF INVENTION

1. Field of Invention

The present invention relates to a display device and control method thereof. More particularly, the present invention relates to a display device having a uniform brightness by controlling an arrangement of light emitting diodes of a light source unit.

2. Description of the Related Art

A display device of a projection type comprises a light source unit emitting light, a micro display unit projecting an image beam by using the light of the light source unit, a reflection mirror reflecting an image beam, and a screen displaying an image by using the image beam.

A lamp generating a depolarized white beam has been widely used as a light source of the light source unit, but recently, a light emitting diode having an excellent color reviving rate is also widely used.

The light emitting diode comprises a red light emitting diode, a green light emitting diode, and a blue light emitting diode. A red light, green light and blue light generated from the light emitting diode are supplied for a micro display unit.

However, the light emitting diode has a limitation, in which a light emitting characteristic, such as brightness, is not uniform due to special characteristics of a manufacturing process therefor. In the case that the light emitting diode having such a non-uniform light emitting characteristic is used, a problem exists in that screen brightness becomes non-uniform. Also, a problem exists in that the red light emitting diode, green light emitting diode, and blue light emitting diode respectively have an independent brightness distribution. As a result, screen color becomes non-uniform.

Accordingly, there is a need for an improved display device comprising an LED light source and a uniform brightness and color.

### SUMMARY OF THE INVENTION

An aspect of exemplary embodiments of the present invention is to address at least the above problems and/or disadvantages and to provide at least the advantages described below. Accordingly, an aspect of exemplary embodiments of the present invention is to provide a display device having uniform brightness and color.

The foregoing and/or other aspects of exemplary embodiments of the present invention can be achieved by providing a display device, that comprises a circuit board having a light emitting diode mounting area, a light source unit comprising a plurality of light emitting diodes mounted to the light emitting diode mounting area so that light emitting characteristics can be symmetrical around the center of the light emitting diode mounting area, a light uniformizing unit for creating a uniform light from the light emitting diodes, a micro display unit located in front of the light uniformizing unit, a projection lens unit located in front of the micro display unit, and a screen located in front of the projection lens unit.

According to an aspect of exemplary embodiments of the present invention, the light source unit comprises a plurality of sub light sources emitting lights different in color each other, and the circuit board comprises a plurality of sub circuit boards spaced from each other. To at least one of the plurality of sub circuit board is mounted at least one of the plurality of sub light sources emitting light of the same color.

According to an aspect of exemplary embodiments of the present invention, the light emitting characteristics comprise at least one of brightness and a main wavelength.

According to an aspect of the present invention, the light emitting diodes are arranged in a matrix shape.

According to an aspect of exemplary embodiments of the present invention, the sub circuit boards comprise three sub circuit boards, at least one of the sub circuit boards is arranged in parallel with a light incident face of the light uniformizing unit, and at least two of the sub circuit boards are arranged perpendicular to the light incident face of the light uniformizing unit.

According to an aspect of exemplary embodiments of the present invention, the display device further comprises a dichroic mirror for reflecting light from the sub circuit board arranged at a predetermined angle to the light incident face of the light uniformizing unit onto the light incident face of the light uniformizing unit.

According to an aspect of exemplary embodiments of the present invention, the light source unit comprises a plurality of sub light sources emitting lights having different colors, light emitting characteristics comprising color of the emitting lights, and at least two of the plurality of sub light sources mounted to the circuit board.

According to an aspect of exemplary embodiments of the present invention, the circuit board is arranged to be in parallel with the light uniformizing unit.

According to an aspect of exemplary embodiments of the present invention, the light uniformizing unit comprises a light tunnel, and a mounting area size suitable for the size of a light incident face of the light tunnel.

According to an aspect of exemplary embodiments of the present invention, the micro display unit comprises a digital micro-mirror display (DMD).

Other objects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other objects, features, and advantages of certain exemplary embodiments of the prevent invention will be more apparent from the following description taken in conjunction with the accompany drawings, in which:

FIG. 1 schematically illustrates a display device according to an exemplary embodiment of the present invention.

FIGS. 2a, 2b, and 2c illustrate a light source unit in a display device according to an exemplary embodiment of the present invention.

FIG. 3 illustrates a light tunnel in a display device according to an exemplary embodiment of the present invention.

FIGS. 4a and 4b illustrate a brightness distribution in a light emitting face of a light tunnel.

FIGS. 5, 6, 7, and 8, respectively, illustrate an arrangement of light emitting diodes in a display device according to an exemplary embodiment of the present invention.

FIG. 9 illustrates a display device according to an exemplary embodiment of the present invention.

FIG. 10 illustrates an arrangement of light emitting diodes in a display device according to an exemplary embodiment of the present invention.

Throughout the drawings, the same drawing reference numerals will be understood to refer to the same elements, features, and structures.

### DETAILED DESCRIPTION OF EXEMPLARY EMBODIMENTS

The matters defined in the description such as a detailed construction and elements are provided to assist in a comprehensive understanding of the embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

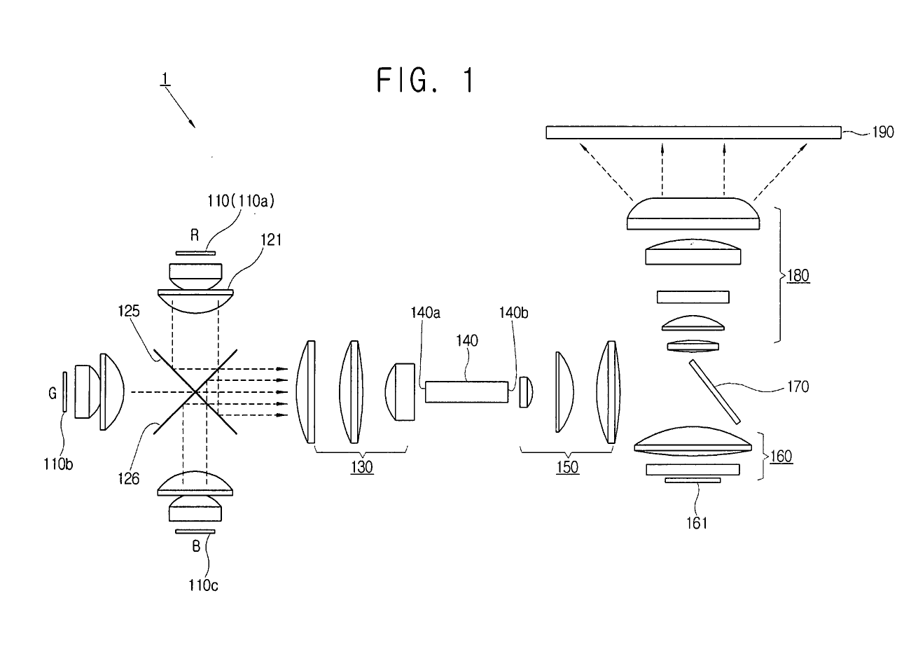

First, a display device according to an exemplary embodiment of the present invention will be described as follows by referring to FIGS. 1, 2, and 3.

As shown in FIG. 1, a display device 1 comprises a light source unit 110, a light tunnel 140 creating uniform light from the light source unit 110, a micro display unit 160 forming an image beam by using the light, a projection lens unit 180 enlarging the image beam, and a screen 190 on which the beam is displayed as a picture.

The light source unit 110 comprises a first sub light unit 110a supplying a red light, a second sub light source unit 110b supplying a green light, and a third sub light source unit 110c supplying a blue light.

The second sub light source unit 110b is arranged in parallel with a light incident face 140a of the light tunnel 140. The first sub light source unit 110a and the third sub light source unit 110c facing each other is perpendicularly disposed to the light incident face 140a of the light tunnel 140.

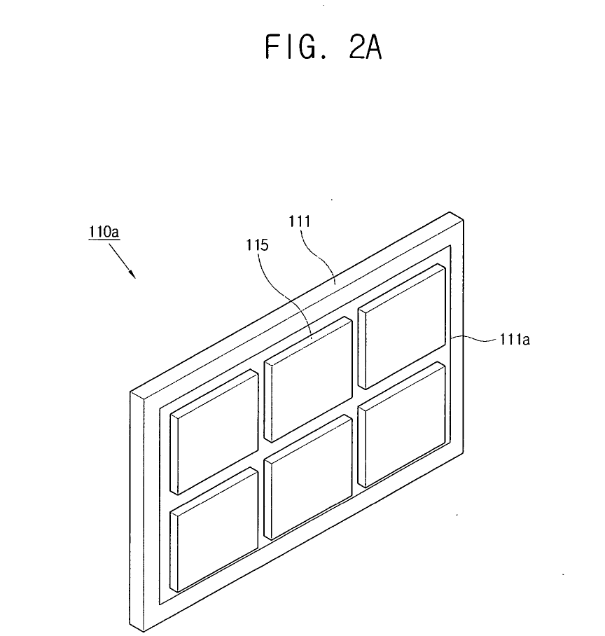

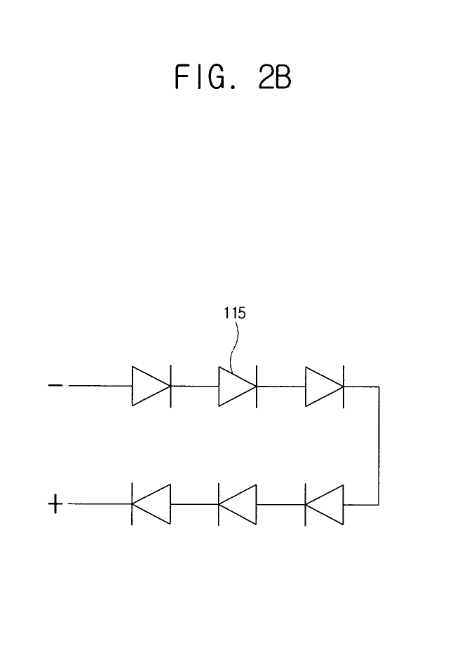

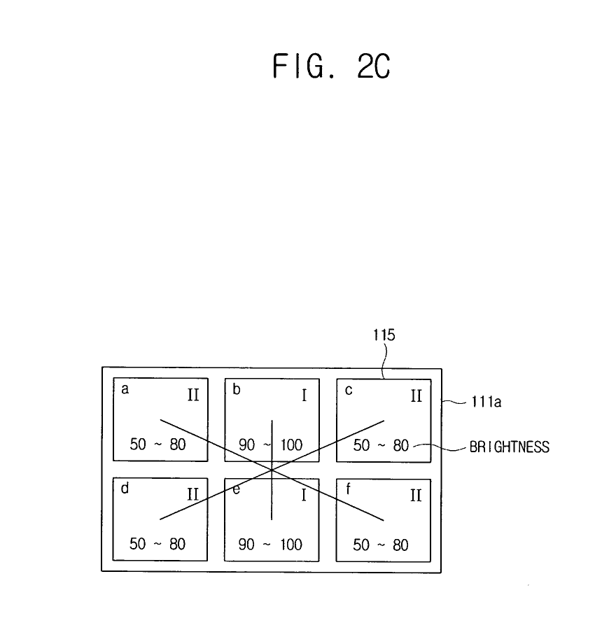

The first sub light source unit 110a will be described below by referring FIGS. 2a to 2c.

The first sub light source unit 110a comprises a rectangular shape circuit board 111 and light emitting diodes 115. In the circuit board 111, a rectangular mounting area 111a is provided and six light emitting diodes 115 are mounted to the mounting area 111a. The light emitting diodes 115 are arranged in a shape of a matrix 2×3. The light emitting diodes 115 are connected to each other in series as shown in FIG. 2b. All the light emitting diodes 115 of the first sub-light source unit 110a emit red lights.

The light emitting diodes 115 are mounted to the circuit board 111 after being separately manufactured. Here, the light emitting diodes 115 having different brightness may be mounted in one circuit board 111.

As shown in FIG. 2c, the six light emitting diodes 115 mounted to the first sub light source unit 110a are divided into a first group I and a second group II according to their brightness. The first group I comprise two light emitting diodes of which the relative brightness is 90 to 100. The first group is positioned in the middle of the circuit board 111. The second group II comprises four light emitting diodes of which relative brightness is somewhat low, for example, 50 to 80. The second group II surrounds the first group.

With this configuration, a light emitting characteristic of the light emitting diodes 115 forms a point symmetry with respect to the center of a light emitting area thereof. Through the arrangement of the light emitting diodes 115, uniform brightness can be obtained.

The second sub light source unit 110b and the third sub light source unit 110c also have configurations similar to that of the first sub light source unit 110a. However, the second sub light emitting unit 110b comprises the light emitting diodes 115 emitting green lights and the third sub light unit 110c comprises the light emitting diode 115 emitting blue lights.

In front of each of the sub light source units 110a, 110b, and 110c, is positioned a collimating lens 121. The light emitted from each of the sub light source units 110a, 110b, and 110c proceeds perpendicularly to the circuit board 111 without being diffused by the collimating lens 121.

Between the second sub light source unit 110b and a first optical lens unit 130 are positioned a first dichroic mirror 125 and a second dichroic mirror 126. The dichroic mirrors 125 and 126 are arranged forming an angle of 45° with respect to the light incident face 140a of the light tunnel 140.

The first dichroic mirror 125 reflects only the red light, and transmits the other color lights. The second dichroic mirror 126 reflects only the blue light, and transmits the other color lights.

The red light emitted from the first sub light source unit 110a is reflected by the first dichroic mirror 125 to be directed to the first optical lens unit 130. The green light emitted from the second sub light source unit 110b transmits both the dichroic mirrors 125 and 126, and directs to the first optical lens unit 130. The blue light emitted from the third sub light source unit 110c is reflected by the second dichroic mirror 126 and then directs to the first optical lens unit 130.

As described above, the lights emitted from all the sub-light source units 110a, 110b, and 110c can be directed to the first optical lens unit 130. The first optical lens unit 130 focuses and supplies the emitted lights for the light tunnel 140. In order to embody a colored screen, as the respective sub light source units 110a, 110b, and 110c are sequentially driven, the red light, the green light, and the blue light are sequentially supplied for the light tunnel 140.

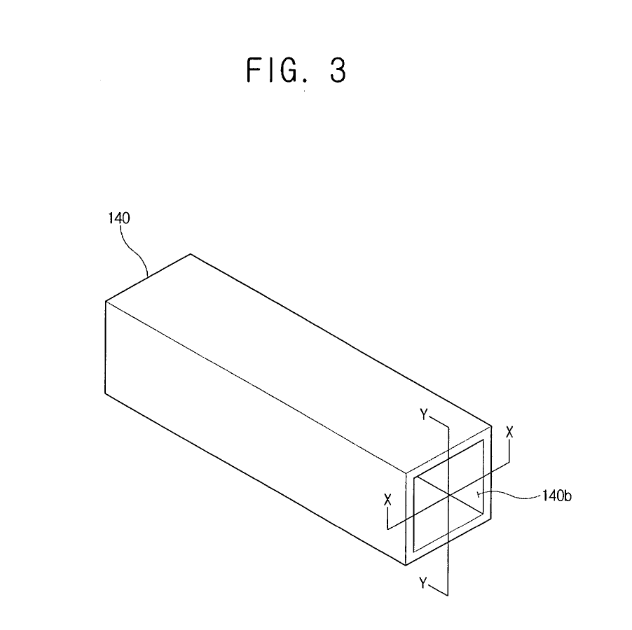

The light tunnel 140 creates a uniform light from the lights. As shown in FIG. 3, the inner surface of the light tunnel 140 having a square cylindrical shape is made of a light reflecting material, similar to a mirror. The lights projected into the light tunnel 140 repeats reflecting in the internal side to form a light having a uniform brightness distribution, which is emitted from the light tunnel 140.

As shown in FIG. 1, the light emitted from the light tunnel 140 is reflected by the reflection mirror 170 via a second optical lens unit 150 and then directed to the micro display unit 160. The micro display unit 160 comprises a digital micro-mirror display (DMD) 161 and controls the DMD 161 to form an image beam.

In addition to certain exemplary embodiments of the present, the micro display unit 160 may comprise a liquid crystal display panel (LCDP) or a liquid crystal on silicon (LCOS).

The image beam emitted from the micro display unit 160 is projected onto the screen 190 via a projection lens unit 180. A fresnel lens, which improves a rectilinear property of the projected beam to increase a frontal brightness, may be formed in the screen 190.

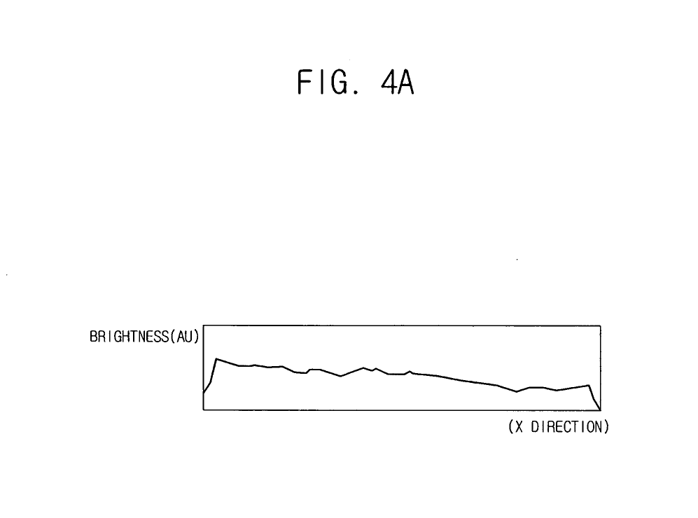

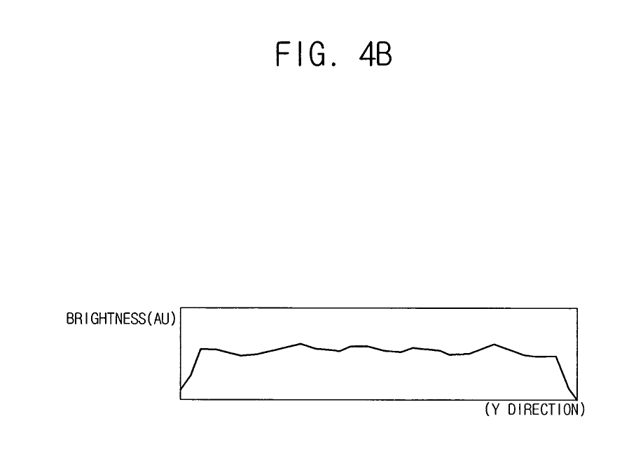

A process of brightness that becomes uniform according to an exemplary embodiment of the present invention will be described below by referring to FIGS. 4a and 4b.

FIGS. 4a and 4b illustrate a brightness distribution on the light exiting face 140b of the light tunnel 140, and a brightness distribution by the light emitted from the light emitting diodes 115 in a position as shown in FIG. 2c.

FIG. 4a illustrates brightness in a position according to line X-X in FIG. 3, and FIG. 4b illustrates brightness in a position according to line Y-Y in FIG. 3.

As shown in the figures, the brightness is relatively uniform along the line Y-Y position, whereas the brightness is not uniform along the line X-X position. That is, light from one of the light emitting diodes 115 is emitted from the light tunnel 140 non-uniformly.

In FIG. 4a, the brightness of the light emitting diode 115 in an ‘f’ position is illustrated on the left thereof, and the brightness of the light emitting diode 115 in an ‘a’ position is illustrated on the right thereof. Here, if the light emitting diodes 115, which are positioned in the ‘a’ position and the ‘f’ position according to an exemplary embodiment of the present invention, have the same brightness, the light emitting diodes 115 compensate for their brightness. Therefore, uniform light can be obtained from the light exiting face 140b of the light tunnel 140.

Turning to FIG. 2c, the light emitting diodes 115 having the same brightness are disposed symmetrically with respect to the center of the mounting area 111a. That is, the light emitting diodes 115 mounted to a ‘b’ position and an ‘e’ position which are mutually symmetrical belong to a first group I, the light emitting diodes 115 mounted to the ‘a’ position and the ‘f’ position which are mutually symmetrical belong to a second group II. Also, the light emitting diodes 115 mounted to a ‘c’ position and a ‘d’ position, which are mutually symmetrical, belong to the second group II.

Accordingly, lights from the light emitting diodes 115 in symmetrical positions compensate for each other to thereby generate a light having a uniform brightness.

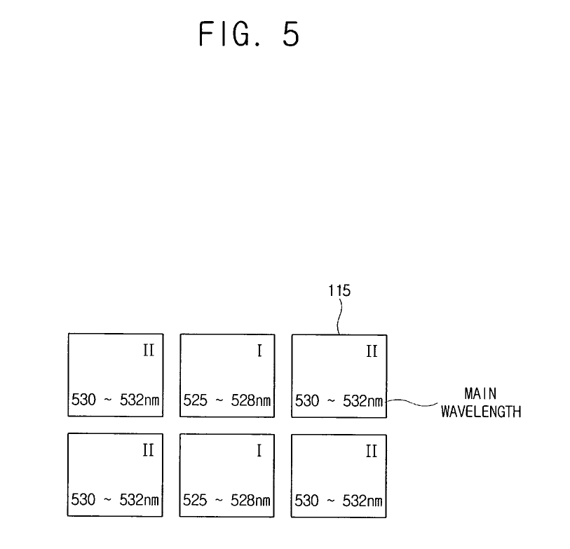

FIGS. 5 through 8 illustrate an arrangement of light emitting diodes in a display device according to an exemplary embodiment of the present invention.

As shown in FIG. 5, in an exemplary embodiment of the present invention, the light emitting diodes 115 are divided into two groups according to their main wavelength. Alternatively, the light emitting diodes 115 may be divided in consideration of both the main wavelength and the brightness, and it may be considered that the main wavelength and the brightness have different weights.

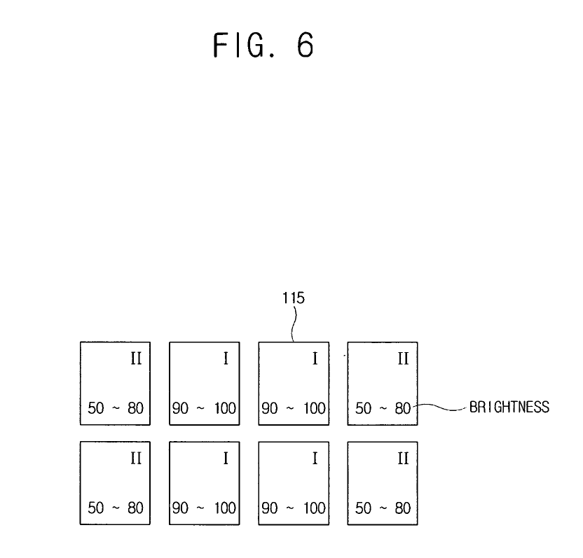

As shown in FIG. 6, in an exemplary embodiment of the present invention, the light emitting diodes 115 are divided into two groups according to their brightness. The first sub light source 110a comprises eight light emitting diodes 115 which are arranged in the shape of a matrix 2×4.

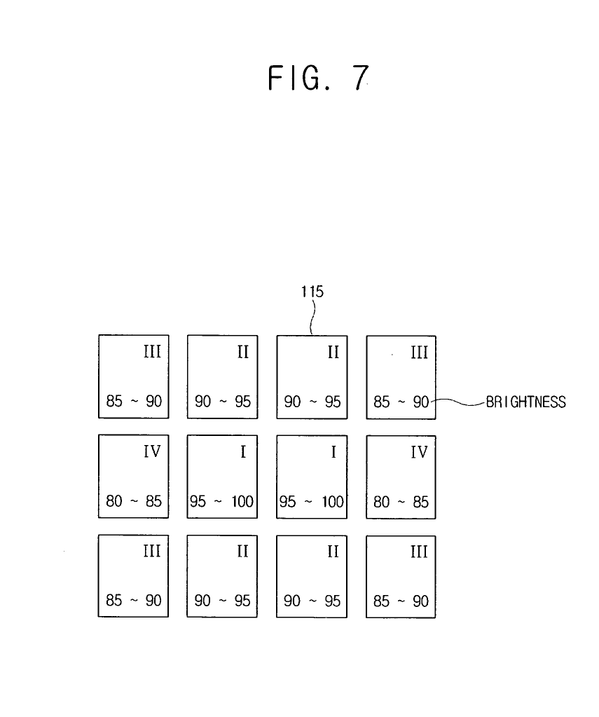

As shown in FIG. 7, in an exemplary embodiment of the present invention, the light emitting diodes 115 are divided into four groups according to their brightness. The first sub light source 110a comprises twelve light emitting diodes 115 which are arranged in the shape of a matrix 3×4.

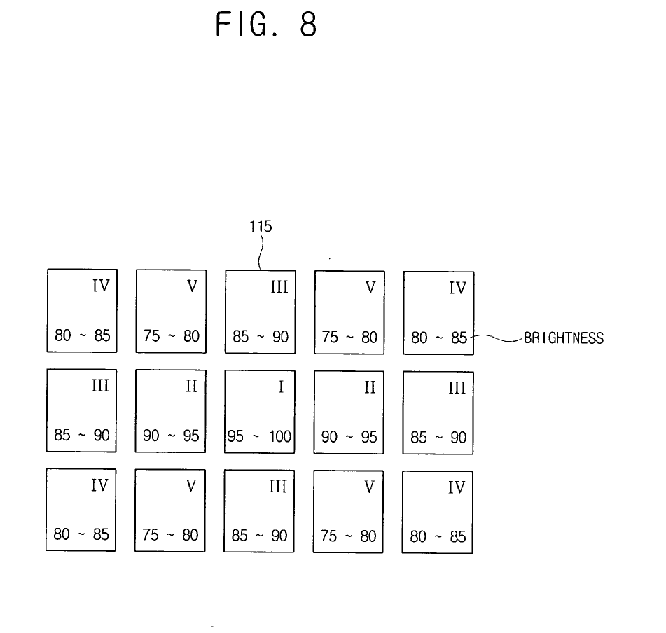

As shown in FIG. 8, in an exemplary embodiment of the present invention, the light emitting diodes 115 are divided into five groups according to their brightness. The first sub light source 110a comprises fifteen light emitting diodes 115 which are arranged in the shape of a matrix 3×5.

In the above exemplary embodiments, the light emitting diodes 115 having the same light emitting characteristics are arranged symmetrically with respect to the center of the mounting area 111a. Accordingly, a uniform light can be obtained from the light exiting face 140b of the light tunnel 140.

In the above exemplary embodiments of the present invention, the mounting area 111a has a rectangular shape, but may be variously changed into a triangular shape, a round shape or the like.

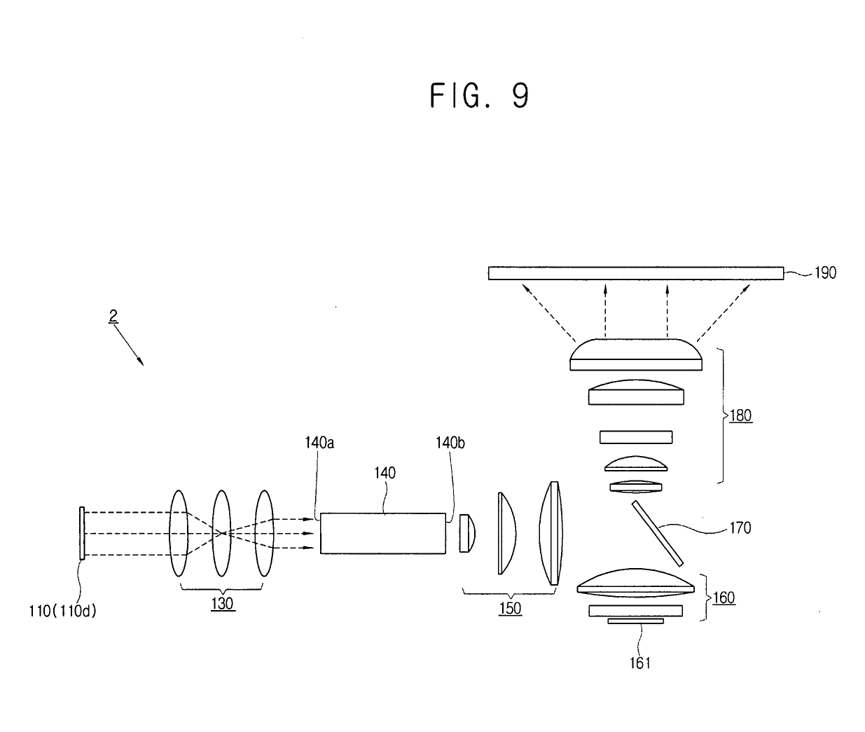

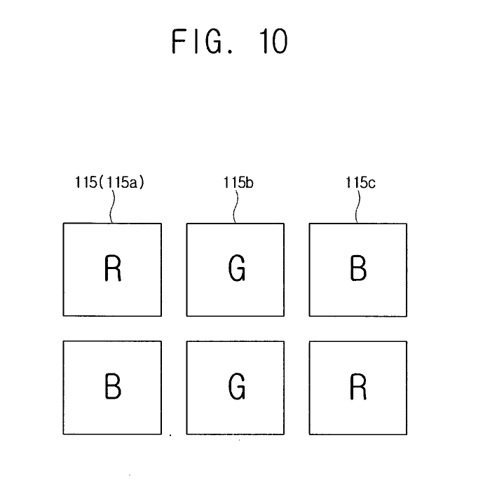

Hereinafter, a display device according to an exemplary embodiment of the present invention will be described by referring to FIGS. 9 and 10.

In a display device 2 according to an exemplary embodiment of the present invention, the light source unit 110 comprises a singular sub light source unit 110d. Six light emitting diodes 115 are positioned in the light source 110. The light emitting diodes 115 comprise a pair of first sub light emitting diodes 115a emitting a red light, a pair of second sub light emitting diodes 115b emitting a green light, and a pair of third sub light emitting diodes 115c emitting a blue light. Here, the pair of first sub light emitting diodes 115a is symmetrically arranged with respect to the center of a mounting area, and the pair of second sub light emitting diodes and the pair of third sub light emitting diodes 115c are symmetrically arranged around the center thereof.

The light from the light exiting face 140a of the light tunnel 140 must have uniform brightness and color. For example, as non-uniform color, compared with non-uniform brightness, is easily recognized by a user. According to an exemplary embodiment of the present invention, as the sub-light emitting diodes 115a, 115b, and 115c compensate for mutual colors, a uniform colored beam can be obtained.

The display device 2 may not be provided with the first optical lens unit 130 as necessary. In an exemplary implementation, the light source unit 110 may be arranged in contact with the light incident face 140a of the light tunnel 140, and the mounting area of the circuit board 111 may be provided to have a size to be suitable for the light incident face 140a of the light tunnel 140.

As described above, a display device according to an exemplary embodiment of the present invention provides uniform brightness and color.

While the invention has been show and described with reference to certain exemplary embodiments thereof, it will be understood by those skilled in the art that various changes in form and details may be made therein without departing from the spirit and scope of the invention as defined by the appended claims and their equivalents.

What is claimed is:

1. A display device, comprising:
a circuit board comprising a light emitting diode mounting area;
a light source unit comprising a plurality of light emitting diodes mounted to the light emitting diode mounting area so that light emitting characteristics can be symmetrical around the center of the light emitting diode mounting area;
a light uniformizing unit for creating uniform light from the light emitting diodes;
a micro display unit located in front of the light uniformizing unit;
a projection lens unit located in front of the micro display unit; and
a screen located in front of the projection lens unit.

2. The display device according to claim 1, wherein the light source unit comprises a plurality of sub light sources emitting lights different in color each other, and the circuit board comprises a plurality of sub circuit boards spaced from each other, and to one of the plurality of sub circuit board is mounted at least one of the plurality of sub light sources emitting light of the same color.

3. The display device according to claim 2, wherein the light emitting characteristics comprise at least one of brightness and a main wavelength.

4. The display device according to claim 2, wherein the light emitting diodes are arranged in a matrix shape.

5. The display device according to claim 3, wherein the light emitting diodes are arranged in a matrix shape.

6. The display device according to claim 2, wherein the sub circuit boards comprise three sub circuit boards,
at least one of the sub circuit boards is arranged in parallel with a light incident face of the light uniformizing unit, and
at least two of the sub circuit boards are arranged at a predetermined angle to the light incident face of the light uniformizing unit.

7. The display device according to claim 6, further comprising a dichroic mirror for reflecting light from the sub circuit board arranged perpendicular to the light incident face of the light uniformizing unit onto the light incident face of the light uniformizing unit.

8. The display device according to claim 1, wherein the light source unit comprises a plurality of sub light sources emitting lights comprising different colors, light emitting characteristics comprising color of the emitting lights, and at least two of the plurality of sub light sources mounted to the circuit board.

9. The display device according to claim 8, wherein the circuit board is arranged in parallel with the light uniformizing unit.

10. The display device according to claim 9, wherein the light uniformizing unit comprises a light tunnel, and
a mounting area comprises a size for a light incident face of the light tunnel.

11. The display device according to claim 1, wherein the micro display unit comprises a digital micro-mirror display (DMD).
